(19) United States
(12) Patent Application Publication
(10) Pub. No.: US 2013/0221891 A1
(43) Pub. Date: Aug. 29, 2013

(54) MOTOR DRIVER HAVING BUILT IN SELF TEST FUNCTION

(71) Applicant: Joo Yul KO, Suwon (KR)

(72) Inventor: Joo Yul KO, Suwon (KR)

(21) Appl. No.: 13/534,776

(22) Filed: Jun. 27, 2012

(30) Foreign Application Priority Data
Feb. 29, 2012 (KR) 10-2012-0021019

(51) Int. Cl. G01R 31/28

(52) U.S. Cl. 318/490

(57) ABSTRACT

There is provided a motor driver having a built-in self test function. The motor driver includes: a test signal generating unit generating a test signal having a preset frequency; a signal processing unit processing an input sensing signal; and a selecting unit selecting one of the test signal from the test signal generating unit and a signal from the signal processing unit. The motor driver further includes: a motor driving controlling unit receiving the signal selected by the selecting unit to perform a motor driving control operation or a preset test.

### CROSS-REFERENCE TO RELATED APPLICATIONS

This application claims the priority of Korean Patent Application No. 10-2012-0021019 filed on Feb. 29, 2012, in the Korean Intellectual Property Office, the disclosure of which is incorporated herein by reference.

### BACKGROUND OF THE INVENTION

1. Field of the Invention

The present invention relates to a motor driver having a built-in self test function, capable of being applied to an information technology (IT) device such as a personal computer, a server, or the like, and performing self testing without a signal applied from the outside in a manufacturing step by embedding a self test function in a motor driver integrated chip (IC).

2. Description of the Related Art

Generally, a motor driver applied to an information technology (IT) device such as a personal computer (PC), a server, or the like, or to an automobile, or the like, includes a motor driver integrated chip (IC) generating a predetermined motor driving signal.

This motor driver IC needs to be tested in order to determine whether or not it is able to operate normally while being manufactured or after having been manufactured.

In the case of most existing motor driver ICs, after a hall signal or a motor encoder signal is applied to the motor driver IC, an actual operation of the motor driver IC, such as whether or not there is an abnormality in the motor driver IC, an actual function of the motor driver IC, or the like, may be confirmed based on a signal output from the motor driver IC.

However, in a test method in an existing motor driver, since a signal should be applied from the outside, it is difficult to test a single unit of the motor driver IC without the signal from the outside, such that it is difficult to manage a manufacturing yield due to defects generated after a module is manufactured.

Patent Document 1 mentioned in the following Related Art Document relates to an apparatus for testing electric motor performance and does not disclose that an operation mode and a test mode may be selected by embedding a self test function.

### [Related Art Document]

(Patent Document 1) U.S. Pat. No. 4,091,662.

### SUMMARY OF THE INVENTION

An aspect of the present invention provides a motor driver having a built-in self test function, capable of reducing a test time by embedding a self test function in a motor driver integrated chip (IC) to perform a self test without a signal applied from the outside in a manufacturing step.

According to an aspect of the present invention, there is provided a motor driver including: a test signal generating unit generating a test signal having a preset frequency; a signal processing unit processing an input sensing signal; and a selecting unit selecting one of the test signal from the test signal generating unit and a signal from the signal processing unit.

The motor driver may further include a motor driving controlling unit receiving the signal selected by the selecting unit to perform a motor driving control operation or a preset test.

The test signal generating unit may include: an oscillator generating a square wave signal having a preset frequency; and a divider dividing the signal from the oscillator according to a preset dividing ratio.

The selecting unit may select the test signal from the test signal generating unit when a preset operation mode control signal is a test mode selection signal and select the signal from the signal processing unit when the operation mode control signal is an operation mode selection signal.

The motor driving controlling unit may perform the preset test based on the signal from the selecting unit when the operation mode control signal is the test mode selection signal and perform the motor driving control operation based on the signal from the selecting unit when the operation mode control signal is the operation mode selection signal.

According to another aspect of the present invention, there is provided a motor driver including: a test signal generating unit generating a test signal having a preset frequency; a selecting unit selecting one of the test signal from the test signal generating unit and a sensing signal from a sensor; and a signal converting unit converting the signal selected by the selecting unit.

The motor driver may further include a motor driving controlling unit receiving a signal converted by the signal converting unit to perform a motor driving control operation or a preset test.

The test signal generating unit may include: an oscillator generating a square wave signal having a preset frequency; a divider dividing the signal from the oscillator according to a preset dividing ratio; and a first low pass filter removing a high frequency component in a signal from the divider.

The selecting unit may select the test signal from the test signal generating unit when a preset operation mode control signal is a test mode selection signal and select the sensing signal from the sensor when the operation mode control signal is an operation mode selection signal.

The motor driving controlling unit may perform the preset test based on the signal from the signal converting unit when the operation mode control signal is the test mode selection signal and perform the motor driving control operation based on the signal from the signal converting unit when the operation mode control signal is the operation mode selection signal.

The test signal generating unit may include: an oscillator generating a square wave signal having a preset frequency; a divider dividing the signal from the oscillator according to a preset dividing ratio; an inverter inverting a signal from the divider; a first low pass filter removing a high frequency component in the signal from the divider; and a second low pass filter removing a high frequency component in a signal from the inverter.

The selecting unit may select the test signal from the test signal generating unit when a preset operation mode control signal is a test mode selection signal and select the sensing signal from the sensor when the operation mode control signal is an operation mode selection signal.

The motor driving controlling unit may perform the preset test based on the signal from the signal converting unit when the operation mode control signal is the test mode selection signal and perform the motor driving control operation based on the signal from the signal converting unit when the operation mode control signal is the operation mode selection signal.

The oscillator may generate a square wave signal having a preset frequency in a frequency range of 1 MHz to 10 MHz.

The divider may divide the square wave signal according to the preset dividing ratio to generate the test signal having the preset frequency.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram of a motor driver according to an embodiment of the present invention;

FIG. 2 is a block diagram of a test signal generating unit according to the embodiment of the present invention;

FIG. 3 is a diagram showing an example of a square wave signal (Sosc) and a test signal (ST) of FIG. 2;

FIG. 4 is a block diagram of a motor driver according to another embodiment of the present invention;

FIG. 5 is a diagram showing a first implementation of a test signal generating unit according to another embodiment of the present invention; and

FIG. 6 is a diagram showing a second implementation of a test signal generating unit according to another embodiment of the present invention.

### DETAILED DESCRIPTION OF THE INVENTION

Embodiments of the present invention will now be described in detail with reference to the accompanying drawings.

The present invention should not be limited to the embodiments set forth herein and the embodiments may be used to assist in understanding the technical idea of the present invention. Like reference numerals designate like components having substantially the same constitution and function in the drawings of the present invention.

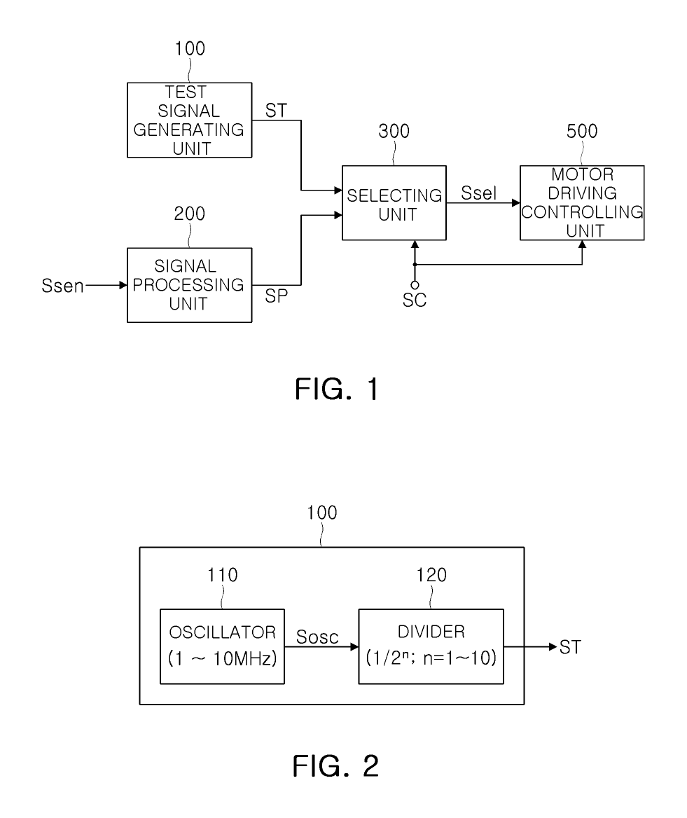

FIG. 1 is a block diagram of a motor driver according to an embodiment of the present invention.

Referring to FIG. 1, the motor driver according to the embodiment of the present invention may include a test signal generating unit 100 generating a test signal ST having a preset frequency, a signal processing unit 200 processing an input sensing signal Ssen, and a selecting unit 300 selecting one of the test signal ST from the test signal generating unit 100 and a signal Sp from the signal processing unit 200.

Here, the test signal generating unit 100, the signal processing unit 200, and the selecting unit 300 may be implemented to be included in a single motor driver integrated chip (IC).

The motor driver according to the embodiment of the present invention may further include a motor driving controlling unit 500 receiving the signal Ssel selected by the selecting unit 300 to perform a motor driving control operation or a preset test.

In this case, the test signal generating unit 100 may generate the test signal ST having a preset frequency to provide the generated test signal ST to the selecting unit 300. Here, the test signal ST, which is generated so that a test may be performed without a signal applied from the outside, may be a square wave signal having a preset frequency in a frequency range of, for example, 10 KHz to 100 KHz.

The signal processing unit 200 may process the input sensing signal Ssen to provide the processed signal to the selecting unit 300. Here, the sensing signal Ssen may correspond to a signal provided from a sensor sensing motor rotations.

For example, in a case in which a sensor outputting a differential signal, such as a hall sensor, is used, since a differential signal is provided from the sensor, the signal processing unit 200 may be implemented as an amplifying circuit capable of converting an analog differential signal from the sensor into a square-wave single ended signal.

Unlike this, in a case in which a sensor outputting a single ended signal, such as an optical sensor, is used, the signal processing unit 200 may be implemented as a decoder capable of converting an analog single ended signal from the sensor into a square-wave single ended signal.

The selecting unit 300 may select one of the test signal ST from the test signal generating unit 100 and the signal Sp from the signal processing unit 200 to provide the selected signal to the motor driving controlling unit 500.

According to each embodiment of the present invention, the test signal generating unit 100, the signal processing unit 200, and the selecting unit 300 maybe implemented to be included in a signal motor driver IC. In this case, since a test signal may be generated in the motor driver IC itself, a self test of the motor driver IC itself may be performed at the time of manufacturing the motor driver or after manufacturing the motor driver.

In addition, the motor driving controlling unit 500 may receive the signal Ssel selected by the selecting unit to perform a motor driving control operation or a preset test.

More specifically, the selecting unit 300 may select the test signal ST from the test signal generating unit 100 in the case in which a preset operation mode control signal SC is a test mode selection signal and select the signal Sp from the signal processing unit 200 in the case in which the operation mode control signal SC is an operation mode selection signal.

In addition, the motor driving controlling unit 500 may perform a preset test based on the signal Ssel from the section unit 300 in the case in which the operation mode control signal SC is the test mode selection signal and control motor driving based on the signal Ssel from the selecting unit 300 in the case in which the operation mode control signal SC is the operation mode selection signal.

Here, the preset test may be a test for confirming whether or not the signal from the selecting unit 300 is matched to a preset motor driving signal, more specifically, a test for a frequency and a level of a signal output from a motor driver IC.

FIG. 2 is a block diagram of a test signal generating unit according to the embodiment of the present invention.

Referring to FIG. 2, the test signal generating unit 100 may include an oscillator 110 generating a square wave signal having a preset frequency and a divider 120 dividing a signal from the oscillator 110 according to a preset dividing ratio.

In this case, the oscillator 110 may generate the square wave signal having the preset frequency to provide the square wave signal to the divider 120. The square wave signal may be, for example, a square wave signal having a frequency of 3 MHz.

In addition, the divider 120 may divide the signal from the oscillator 110 according to the preset dividing ratio. For example, when the dividing ratio is 1/300, a test signal ST provided from the divider 120 may have a frequency of 10 KHz (=3 MHz/300).

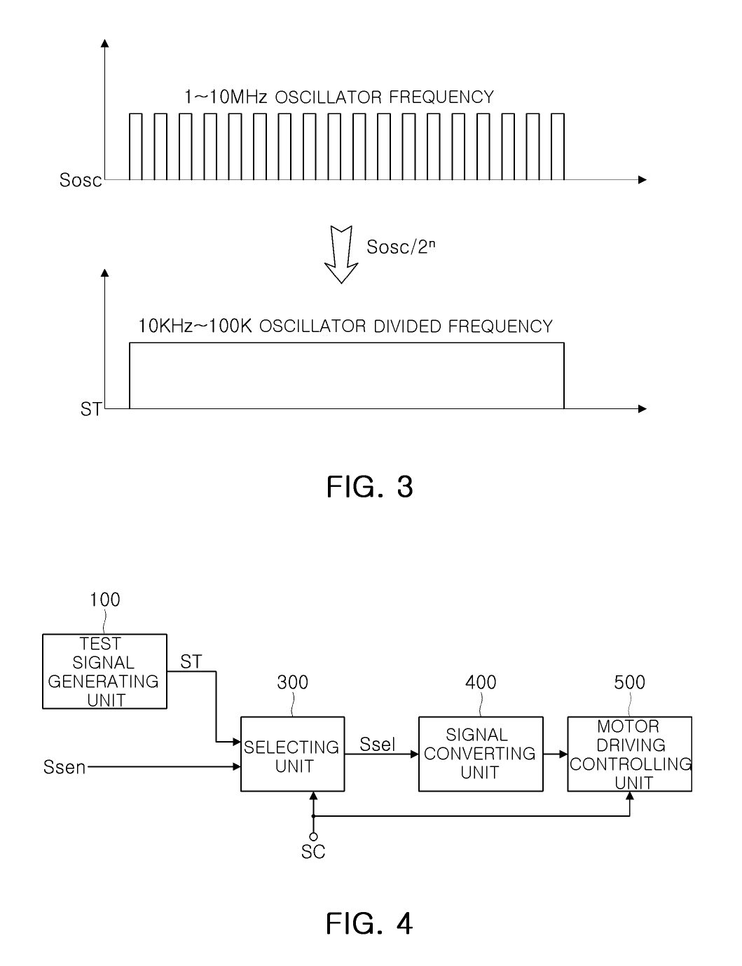

FIG. 3 is a diagram showing an example of a square wave signal (Sosc) and a test signal (ST) of FIG. 2.

Referring to FIGS. 2 and 3, the oscillator 110 may generate a square wave signal having a preset frequency in a frequency range of 1 MHz to 10 MHz.

In addition, the divider 120 may divide the square wave signal according to a preset dividing ratio to generate the test signal ST having a preset frequency.

In this case, the oscillator 110 may generate the square wave signal having the preset frequency in the frequency range of 1 MHz to 10 MHz. The square wave signal Sosc may be a square wave signal having a frequency preset to 3 MHz in the frequency range of 1 MHz to 10 MHz.

In addition, the divider 120 may divide the square wave signal according to the preset dividing ratio to generate the test signal ST having the preset frequency. For example, when a range of the dividing ratio is ‘1/2ⁿ’ (n=1 to 10), the test signal ST may be determined to be ‘Sosc/2^{N}’. Therefore, in the case in which ‘1/2⁸=256’, the test signal ST may be a square wave signal having a frequency of ‘11.72 KHz (3 MHz/256)’.

The above-mentioned description may be applied to each embodiment of the present invention.

FIG. 4 is a block diagram of a motor driver according to another embodiment of the present invention.

Referring to FIG. 4, the motor driver according to another embodiment of the present invention may include a test signal generating unit 100 generating a test signal ST having a preset frequency, a selecting unit 300 selecting one of the test signal ST from the test signal generating unit 100 and a sensing signal Ssen from a sensor, and a signal converting unit 400 converting a signal Ssel from the selecting unit 300.

The motor driver according to another embodiment of the present invention may further include a motor driving controlling unit 500 receiving the signal Ssel selected by the signal converting unit 400 to perform a motor driving control operation or a preset test.

In this case, the test signal generating unit 100 may generate the test signal ST having a preset frequency to provide the generated test signal ST to the selecting unit 300. Here, the test signal ST may be, for example, a square wave signal having a preset frequency in a frequency range of 10 KHz to 100 KHz.

The selecting unit 300 may select one of the test signal ST from the test signal generating unit 100 and the sensing signal Ssen from the sensor. Here, the sensing signal Ssen may correspond to a signal provided from a sensor sensing motor rotations.

For example, in a case in which a sensor outputting a differential signal, such as a hall sensor, is used, the sensing signal Ssen may be a differential signal. Unlike this, in a case in which a sensor outputting a single ended signal, such as an optical sensor, is used, the sensing signal Ssen may be a single ended signal.

In addition, the signal converting unit 400 may convert the signal Ssel from the selecting unit 300 into a signal having a level that may be processed in the motor driving controlling unit 500.

For example, in the case in which a sensor outputting a differential signal, such as a hall sensor, is used, since the sensing signal is a differential signal, the signal converting unit 400 may be implemented as an amplifying circuit capable of converting an analog differential signal into a square wave single ended signal.

Unlike this, in the case in which a sensor outputting a single ended signal, such as an optical sensor, is used, the signal converting unit 400 may be implemented as a decoder capable of converting an analog single ended signal into a square-wave single ended signal.

In addition, referring to FIG. 4, the selecting unit 300 may select the test signal ST from the test signal generating unit 100 in the case in which a preset operation mode control signal SC is a test mode selection signal and select the sensing signal from the sensor in the case in which the operation mode control signal SC is an operation mode selection signal.

In this case, the motor driving controlling unit 500 may perform a preset test based on the signal from the signal converting unit 400 in the case in which the operation mode control signal SC is the test mode selection signal and control motor driving based on the signal from the signal converting unit 400 in the case in which the operation mode control signal SC is the operation mode selection signal.

The configurations and operations of the selecting unit 300, the signal converting unit 400, and the motor driving controlling unit 500 are the same as those of the previous embodiment. Therefore, a detailed description of an overlapped portion will be omitted.

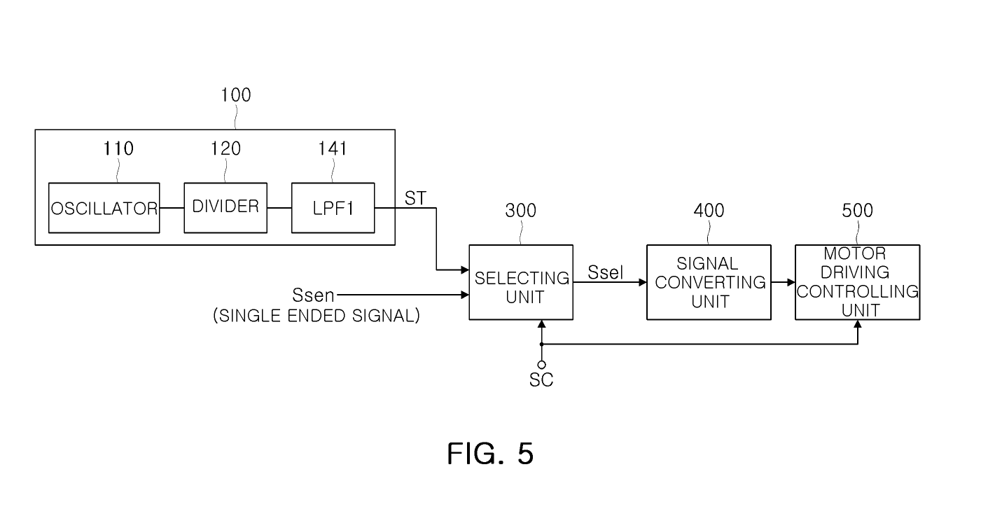

FIG. 5 is a diagram showing a first implementation of a test signal generating unit according to another embodiment of the present invention.

Referring to FIG. 5, the test signal generating unit 100 may include an oscillator 110 generating a square wave signal having a preset frequency, a divider 120 dividing a signal from the oscillator 110 according to a preset dividing ratio, and a first low pass filter 141 removing a high frequency component in a signal from the divider 120.

In this case, the oscillator 110 may generate the square wave signal having the preset frequency to provide the square wave signal to the divider 120. The square wave signal may be, for example, a square wave signal having a frequency of 3 MHz.

The divider 120 may divide the signal from the oscillator 110 according to the preset dividing ratio. For example, when the dividing ratio is 1/300, a test signal ST provided from the divider 120 may have a frequency of 10 KHz (=3 MHz/300).

In addition, the first low pass filter 141 may remove the high frequency component in the signal from the divider 120. Therefore, a signal output from the first low pass filter 141 may be converted into an analog signal having the same form as that of the sensing signal input from the sensor.

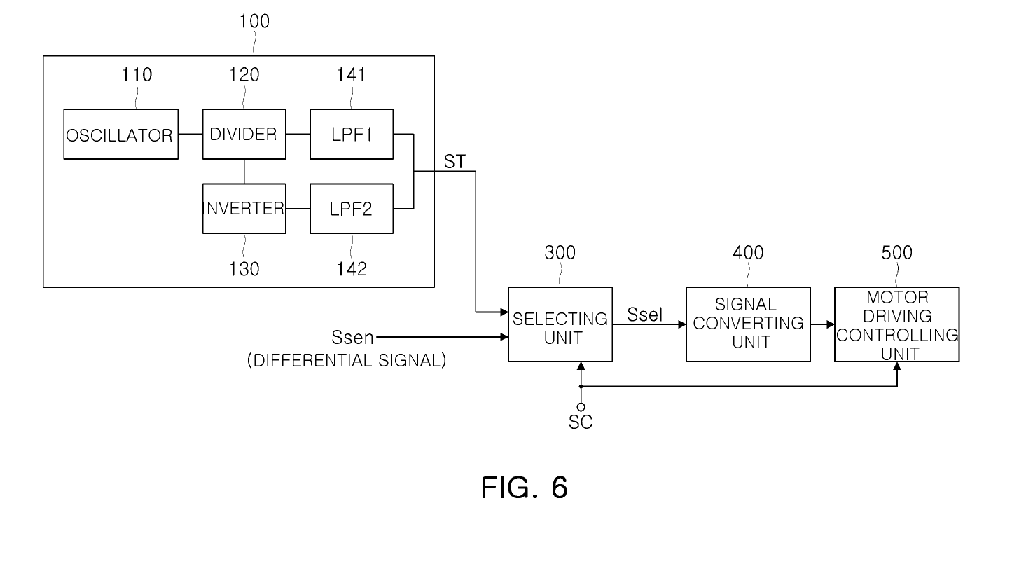

FIG. 6 is a diagram showing a second implementation of a test signal generating unit according to another embodiment of the present invention.

Referring to FIG. 6, the test signal generating unit 100 may include an oscillator 110 generating a square wave signal having a preset frequency, a divider 120 dividing a signal from the oscillator 110 according to a preset dividing ratio, an inverter 130 inverting a signal from the divider 110, a first low pass filter 141 removing a high frequency component in the signal from the divider 120, and a second low pass filter 142 removing a high frequency component in a signal from the inverter 130.

In this case, the oscillator 110 may generate the square wave signal having the preset frequency to provide the square wave signal to the divider 120. The square wave signal may be, for example, a square wave signal having a frequency of 3 MHz.

The divider 120 may divide the signal from the oscillator 110 according to the preset dividing ratio to provide the divided signal to the first low pass filter 141. For example, when the dividing ratio is 1/300, a test signal ST provided from the divider 120 may have a frequency of 10 KHz (=3 MHz/300).

The inverter 130 may invert the signal from the divider 120 to provide the inverted signal to the second low pass filter 142. Here, the inverter 130 is required in order to generate a differential signal corresponding to the sensing signal Ssen, which is a differential signal.

The first low pass filter 141 may remove the high frequency component in the signal from the divider 120. Therefore, a signal output from the first low pass filter 141 may be converted into an analog signal in the same form as that of the sensing signal input from the sensor.

In addition, the second low pass filter 142 may remove the high frequency component in the signal from the inverter 130. Therefore, a signal output from the second low pass filter 142 may be converted into an analog signal in the same form as that of the sensing signal input from the sensor.

As described above, the motor driver according to the embodiments of the present invention may be applied to an IT device such as a personal computer, a server, or the like, a mobile electronic device such as a cellular phone, an automobile, or the like. As set forth above, according to the embodiments of the present invention, a self test function is embedded in the motor driver IC to perform self testing without a signal applied from the outside, whereby a test time may be reduced and the motor driver IC may be tested even after being manufactured.

While the present invention has been shown and described in connection with the embodiments, it will be apparent to those skilled in the art that modifications and variations can be made without departing from the spirit and scope of the invention as defined by the appended claims.

What is claimed is:

1. A motor driver comprising:
a test signal generating unit generating a test signal having a preset frequency;
a signal processing unit processing an input sensing signal; and
a selecting unit selecting one of the test signal from the test signal generating unit and a signal from the signal processing unit.

2. The motor driver of claim 1, further comprising a motor driving controlling unit receiving the signal selected by the selecting unit to perform a motor driving control operation or a preset test.

3. The motor driver of claim 1, wherein the test signal generating unit includes:
an oscillator generating a square wave signal having a preset frequency; and
a divider dividing the signal from the oscillator according to a preset dividing ratio.

4. The motor driver of claim 3, wherein the oscillator generates a square wave signal having a preset frequency in a frequency range of 1 MHz to 10 MHz.

5. The motor driver of claim 4, wherein the divider divides the square wave signal according to the preset dividing ratio to generate the test signal having the preset frequency.

6. The motor driver of claim 5, wherein the selecting unit selects the test signal from the test signal generating unit when a preset operation mode control signal is a test mode selection signal, and selects the signal from the signal processing unit when the operation mode control signal is an operation mode selection signal.

7. The motor driver of claim 6, wherein the motor driving controlling unit performs the preset test based on the signal from the selecting unit when the operation mode control signal is the test mode selection signal, and performs the motor driving control operation based on the signal from the selecting unit when the operation mode control signal is the operation mode selection signal.

8. A motor driver comprising:
a test signal generating unit generating a test signal having a preset frequency;
a selecting unit selecting one of the test signal from the test signal generating unit and a sensing signal from a sensor; and
a signal converting unit converting the signal selected by the selecting unit.

9. The motor driver of claim 8, further comprising a motor driving controlling unit receiving a signal converted by the signal converting unit to perform a motor driving control operation or a preset test.

10. The motor driver of claim 8, wherein the test signal generating unit includes:
an oscillator generating a square wave signal having a preset frequency;
a divider dividing the signal from the oscillator according to a preset dividing ratio; and
a first low pass filter removing a high frequency component in a signal from the divider.

11. The motor driver of claim 10, wherein the oscillator generates a square wave signal having a preset frequency in a frequency range of 1 MHz to 10 MHz.

12. The motor driver of claim 11, wherein the divider divides the square wave signal according to the preset dividing ratio to generate the test signal having the preset frequency.

13. The motor driver of claim 12, wherein the selecting unit selects the test signal from the test signal generating unit when a preset operation mode control signal is a test mode selection signal, and selects the sensing signal from the sensor when the operation mode control signal is an operation mode selection signal.

14. The motor driver of claim 13, wherein the motor driving controlling unit performs the preset test based on the signal from the signal converting unit when the operation mode control signal is the test mode selection signal, and performs the motor driving control operation based on the signal from the signal converting unit when the operation mode control signal is the operation mode selection signal.

15. The motor driver of claim 8, wherein the test signal generating unit includes:
an oscillator generating a square wave signal having a preset frequency;
a divider dividing the signal from the oscillator according to a preset dividing ratio;
an inverter inverting a signal from the divider;
a first low pass filter removing a high frequency component in the signal from the divider; and
a second low pass filter removing a high frequency component in a signal from the inverter.

16. The motor driver of claim 15, wherein the oscillator generates a square wave signal having a preset frequency in a frequency range of 1 MHz to 10 MHz.

17. The motor driver of claim 16, wherein the divider divides the square wave signal according to the preset dividing ratio to generate the test signal having the preset frequency.

18. The motor driver of claim 17, wherein the selecting unit selects the test signal from the test signal generating unit when a preset operation mode control signal is a test mode selection signal, and selects the sensing signal from the sensor when the operation mode control signal is an operation mode selection signal.

19. The motor driver of claim 18, wherein the motor driving controlling unit performs the preset test based on the signal from the signal converting unit when the operation mode control signal is the test mode selection signal, and performs the motor driving control operation based on the signal from the signal converting unit when the operation mode control signal is the operation mode selection signal.
